(19) United States
(12) Patent Application Publication
(10) Pub. No.: US 2024/0421114 A1
(43) Pub. Date: Dec. 19, 2024

(54) METHOD OF MANUFACTURING SEMICONDUCTOR DEVICE AND SEMICONDUCTOR DEVICE

(71) Applicant: Mitsubishi Electric Corporation, Tokyo (JP)

(72) Inventor: Norikazu SAKAI, Fukuoka (JP)

(73) Assignee: Mitsubishi Electric Corporation, Tokyo (JP)

(21) Appl. No.: 18/624,087

(22) Filed: Apr. 1, 2024

(30) Foreign Application Priority Data
Jun. 16, 2023 (JP) 2023-099253

(51) Int. Cl. H01L 23/00

(52) U.S. Cl. CPC H01L 24/29; H01L 24/32; H01L 24/83; H01L 2224/29015; H01L 2224/32054; H01L 2224/32225; H01L 2224/32245; H01L 2224/83201

(57) ABSTRACT

A manufacturing method of a semiconductor device includes the steps of supplying a paste-like bonding material on a base material, pressing down the bonding material with an object to be bonded, and bonding the object to be bonded onto the base material by the bonding material. The object to be bonded is rectangular. The bonding material supplied onto the base material includes a central portion located at a center of the object to be bonded, an extended portion extending from the central portion toward each vertex of the object to be bonded, and a retreated portion that is retreated from each side of the object to be bonded. A distance of 40 μm or more is secured from an upper surface of the object to be bonded to an upper end of the bonding material that has crept up along a side surface of the object to be bonded.

### BACKGROUND OF THE INVENTION

### Field of the Invention

The present disclosure relates to a method of manufacturing a semiconductor device and a structure of the semiconductor device, and particularly relates to a technique for bonding an object to be bonded, such as a semiconductor chip, onto a base material such as a substrate using a paste-like bonding material.

### Description of the Background Art

In the manufacturing of general semiconductor devices, when bonding a semiconductor chip onto a substrate, first, supply molten solder to the front surface of the substrate, or melt the solder on the substrate, next, place the semiconductor chip on top of the molten solder and press down the solder, this allows the solder to be wetting and spread over the entire bottom surface of the semiconductor chip, and then the solder is solidified, thereby the semiconductor chip is bonded to the substrate. Due to the solder spreading concentrically, when pressing down the solder with the semiconductor chip, the solder does not spread to the corners of the semiconductor chip, and the corners of the semiconductor chip are prone to have poor solder wetting.

For example, in Japanese Patent Application Laid-Open No. 2011-238647 in the following, a technique is disclosed in which, provided on a substrate is a semiconductor chip having an intersection below the center thereof to which the solder is supplied in the cross shape extending toward the four corners of the semiconductor chip, thereby allowing the solder to spread to the corners of the semiconductor chip.

In addition, as described in Japanese Patent Application Laid-open No. 2014-29897 below, in manufacturing semiconductor devices using typical sintered bonding materials (hereinafter referred to as “sintered materials”), a paste-like sintered material is supplied in the same form as the semiconductor chip and the sintered material is dried, then the semiconductor chip is placed thereon, the semiconductor chip is bonded to the substrate by applying pressure and heating. Japanese Patent Application Laid-Open No. 2014-29897 discloses a technique that controls a sintered density of a sintered material.

The problem to be solved is that the spread to the corners of the semiconductor chip of a bonding material and control of a sintered density are both to be established.

Further, in a case where solder is adopted as a bonding material, when the pressed down solder by the semiconductor chip is displaced from the semiconductor chip, the surface tension alters the shape of the solder, hampering the solder from creeping up along the side surfaces of the semiconductor chip where wetting with the solder is unlikely. However, when a paste-like sintered material is adopted as the bonding material, no shape alteration due to surface tension occurs, allowing the sintered material to creep up along the side surfaces of the semiconductor chip. The sintered material creeping up along the side surfaces of the semiconductor chip increases leakage current when it is subjected to Temperature Humidity Bias Test (THB test), etc., resulting in a problem of reduced reliability.

### SUMMARY

An object of the present disclosure is to, when bonding an object to be bonded onto a base material using a paste-like bonding material, establish the spread to the corners of the object to be bonded of a bonding material and control of a density of a bonding material, along with to contribute to improving the reliability of the semiconductor device.

A method of manufacturing a semiconductor device includes the steps of (a) supplying a paste-like bonding material on a base material, and (b) placing an object to be bonded on the bonding material, pressing down the bonding material with the object to be bonded, and bonding the object to be bonded onto the base material by the bonding material. The object to be bonded has a rectangular shape in plan view. In the step (a), when the object to be bonded is placed on the bonding material, the bonding material supplied onto the base material includes a central portion located at a center of the object to be bonded, an extended portion extending from the central portion toward each vertex of the object to be bonded and having a shape corresponding to a corner shape of each vertex of the object to be bonded, and a retreated portion that is retreated from each side of the object to be bonded. After the step (b), a distance of 40 μm or more is secured from an upper surface of the object to be bonded to an upper end of the bonding material that has crept up along a side surface of the object to be bonded.

According to the present disclosure, when bonding an object to be bonded onto a base material using a paste-like bonding material, the spread to the corners of the object to be bonded of a bonding material and control of a density of a bonding material are established, along with the contribution to improving the reliability of the semiconductor device.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram illustrating a step of bonding an object to be bonded onto a base material in a method of manufacturing a semiconductor device according to Embodiment;

FIG. 2 is a diagram illustrating a step of bonding the object to be bonded onto the base material in the method of manufacturing the semiconductor device according to Embodiment;

FIG. 3 is a diagram illustrating a step of bonding the object to be bonded onto the base material in the method of manufacturing the semiconductor device according to Embodiment;

FIG. 4 is a diagram illustrating a step of bonding the object to be bonded onto the base material in the method of manufacturing the semiconductor device according to Embodiment;

FIG. 5 is a diagram illustrating an image of the object to be bonded bonded onto the base material using the method of manufacturing the semiconductor device according to Embodiment;

FIG. 6 is a diagram illustrating an enlarged image of an area surrounded by a square in FIG. 5;

FIG. 7 is a graph illustrating the observation results of the distance from the upper surface of a semiconductor chip that failed in the THB test to the upper end of the bonding material;

FIG. 8 is a diagram illustrating an image of the bonding material near the center of the object to be bonded;

FIG. 9 is a diagram illustrating an image of the bonding material near the vertex of the object to be bonded; and

FIG. 10 is a diagram illustrating an image of the bonding material observed near a side of the objects to be bonded.

### DESCRIPTION OF THE PREFERRED EMBODIMENTS

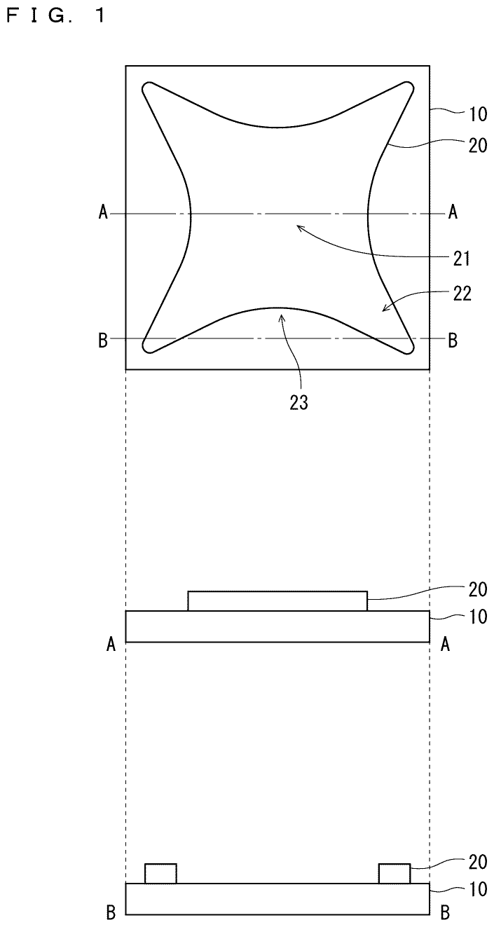

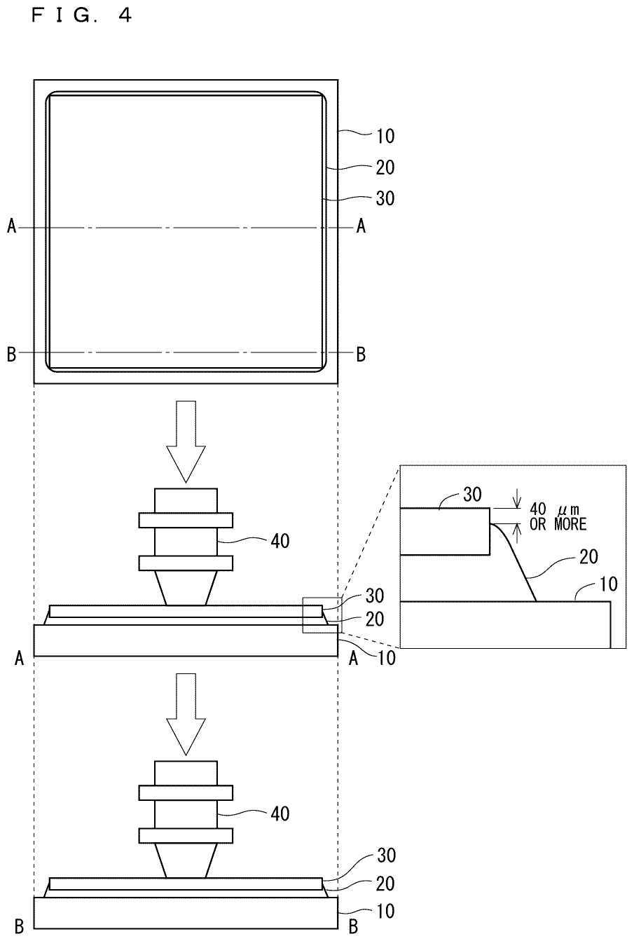

FIGS. 1 to 4 are diagrams illustrating steps of bonding an object to be bonded 30 onto a base material 10 in a method of manufacturing a semiconductor device according to Embodiment of the technique of the present disclosure. In FIGS. 1 to 4, the top row illustrates a plan view, the middle row illustrates a cross-sectional view taken along the line A-A of the top view, and the bottom row illustrates a cross-sectional view taken along the line B-B of the top view. Further, FIG. 4 also illustrates an enlarged view of the end portion in the cross-sectional view taken along the line A-A.

First, as illustrated in FIG. 1, a paste-like bonding material 20 is supplied onto the base material 10. The base material 10 is, for example, an insulating substrate, a heat sink, etc., and has a larger area than the object to be bonded 30. The object to be bonded 30 is, for example, a semiconductor chip, an insulating substrate, a terminal, etc., and has a rectangular shape in plan view. The paste-like bonding material 20 is, for example, a sintered material made of metal such as silver (Ag) and having a melting point of 400° C. or lower, or a non-melting bonding material such as a conductive adhesive. The bonding material 20 is supplied to an area that is equal to or smaller than the outer dimension of the object to be bonded 30.

In Embodiment, the base material 10 is an insulating substrate, the object to be bonded 30 is a semiconductor chip, and the bonding material 20 is a sintered material made of silver. Note that the material of the semiconductor chip may be silicon or a wide bandgap semiconductor such as silicon carbide (SiC). A semiconductor device formed using a wide bandgap semiconductor is superior in operation at high voltages, large currents, and high temperatures, compared to conventional semiconductor devices using silicon. A wide bandgap semiconductor includes, for example, gallium nitride (GaN)-based materials, diamond, and the like, along with silicon carbide.

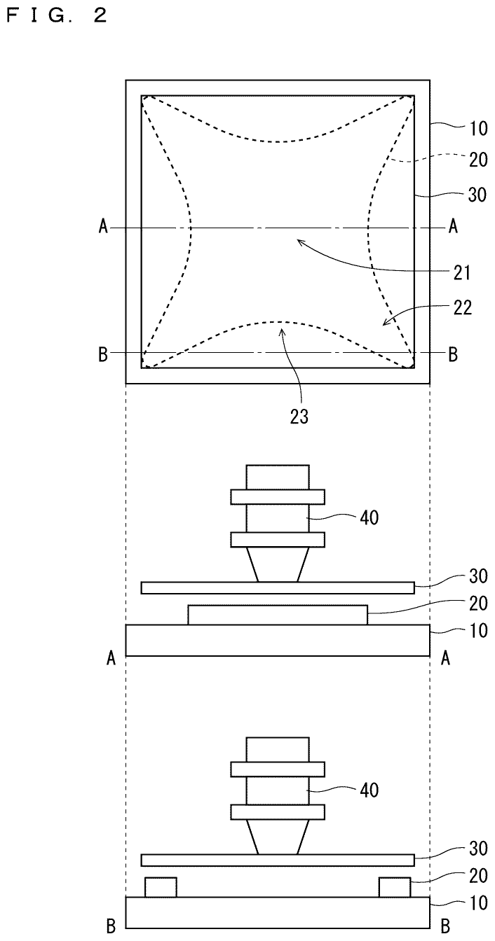

Next, as illustrated in FIG. 2, the object to be bonded 30 is positioned on the bonding material 20 with the object to be bonded 30 being adsorbed to a collet 40. As illustrated in FIGS. 1 and 2, when the object to be bonded 30 is placed on the bonding material 20, the bonding material 20 supplied onto the base material 10 includes a central portion 21 located at the center of the object to be bonded 30, an extended portion 22 extending from the central portion 21 toward each vertex (corner) of the object to be bonded 30 and having a shape corresponding to the corner shape of each vertex of the object to be bonded 30, and a retreated portion 23 that is retreated from each side of the object to be bonded 30.

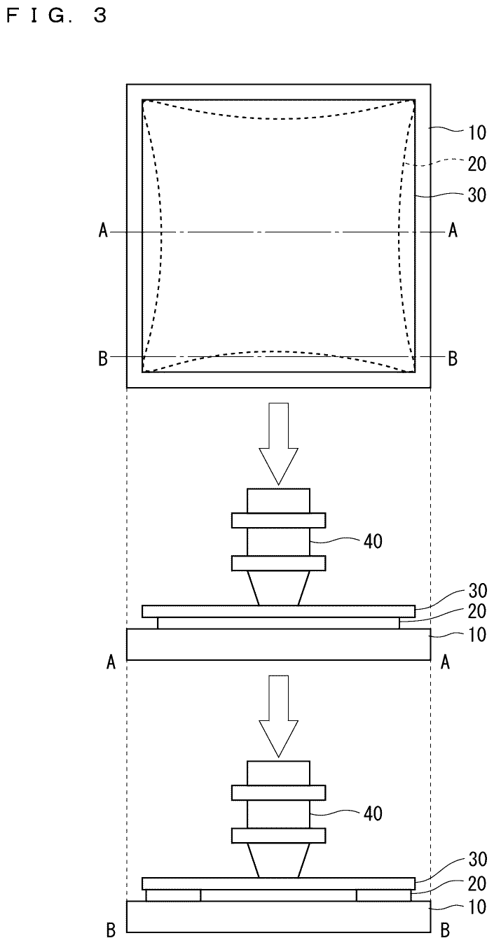

Then, as illustrated in FIG. 3, with the object to be bonded 30 being placed on the bonding material 20, the object to be bonded 30 is pressed against the paste-like bonding material 20 using the collet 40 at a pressure of 0.05 MPa or less to press down the bonding material 20. Accordingly, the bonding material 20 is pressed and spread over the entire lower surface of the object to be bonded 30, as illustrated in FIG. 4. The portion of the bonding material 20 that is formed by the retreated portion 23 being pressed and spread reaches each side of the rectangular object to be bonded 30, and then, the portion of the bonding material 20 that has gone over each side of the object to be bonded 30 creeps up along the side surface of the object to be bonded 30. At this point, as illustrated in the enlarged view of the end portion of the object to be bonded 30 illustrated in FIG. 4, a distance of 40 μm or more is secured from the upper surface of the object to be bonded 30 to the upper end of the bonding material 20 that has crept up along the side surface of the object to be bonded 30. And, the tip of the portion of the bonding material 20 that is formed by the extended portion 22 being pressed and spread is to be aligned with the position of the vertex of the object to be bonded 30.

Then, the object to be bonded 30 and the base material 10 are bonded to each other via the bonding material 20 by heating in the state illustrated in FIG. 4. The bonding material 20 is a non-melting bonding material; therefore, the shape of the bonding material 20 is maintained even during the bonding process of heating. Note that when a sintered material is adopted as the bonding material 20, unlike soldering, the bonding process of heating may be performed without applying pressure, that is, with zero pressure.

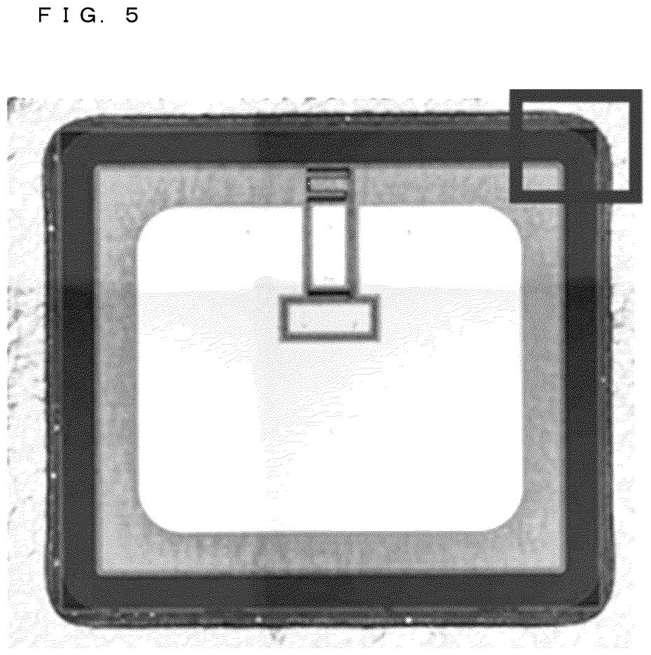

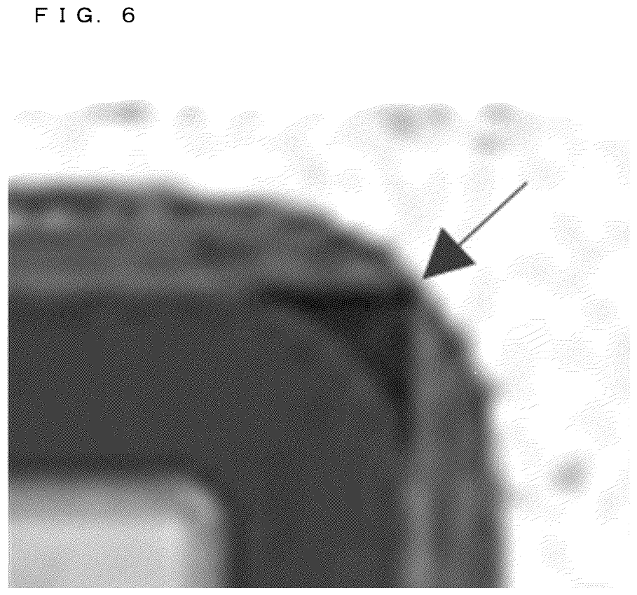

FIG. 5 is an image observed of the object to be bonded 30 bonded to the base material 10 via the bonding material 20, and FIG. 6 is an enlarged image of the area surrounded by the square in the upper right corner of FIG. 5. Despite the bonding material 20 being pressed and spread until it is pushed out of each side of the object to be bonded 30, the amount of the bonding material 20 pushed out of each side creeps up along the side surface of the object to be bonded 30 is miniscule, as illustrated in FIG. 5. This allows the interval between the objects to be bonded 30, when a plurality thereof are aligned and bonded, to be as narrow as about 0.5 mm.

Further, the bonding material 20 that has been pressed and spread reaches the corners of the object to be bonded 30. However, due to the tip of the portion where the extended portion 22 of the bonding material 20 that has been pressed and spread being enabled to be aligned with the position of the vertex of the object to be bonded 30, the bonding material 20 is prevented from protruding from the corner of the object to be bonded 30 (the portion indicated by an arrow) as illustrated in FIG. 6. Stress concentration due to thermal stress is reduced because of the bonding material 20 reaching the corners of the objects to be bonded 30, suppressing cracks from occurring in the bonding material 20. Moreover, the effect of improving the heat dissipation of the object to be bonded 30 can also be obtained.

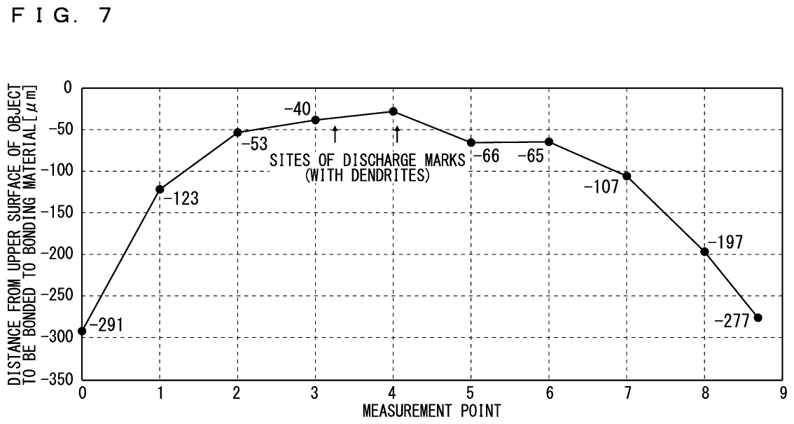

For the semiconductor device manufactured by the method of manufacturing a semiconductor device according to Embodiment (the base material 10 is an insulating substrate, the object to be bonded 30 is a semiconductor chip, and the bonding material 20 is a sintered material made of silver), the THB test was conducted in which a voltage of 2970 V was applied in an environment with a temperature of 90° C. and humidity of 90%. As a result, a defect occurred in which the leakage current increased 1000 hours after the start of the test. When observing the area around the area with discharge marks on the semiconductor chip with increased leakage current using an optical microscope (Hisomet (registered trademark)), as illustrated in FIG. 7, it was confirmed that the distance from the upper surface of the semiconductor chip to the upper end of the bonding material that has crept up along the side surface of the semiconductor chip was less than 40 μm at that location. Whereas, no defect occurred with the semiconductor chip that has a distance of 40 μm or more from the upper surface thereof to the upper end of the bonding material. Therefore, securing the distance of 40 μm or more from the upper surface of the semiconductor chip to the upper end of the bonding material can contribute to improving the reliability of the semiconductor device.

In particular, when a sintered material made of silver (Ag) is adopted as the bonding material, the creeping up of Ag onto the side surface of the semiconductor chip has the disadvantage of inducing Ag electromigration. However, as in Embodiment, by securing the distance of 40 μm or more from the upper surface of the semiconductor chip to the upper end of the bonding material, the effect of avoiding the occurrence of Ag electromigration can also be obtained.

Here, the density of the bonding material 20 will be described. When the paste-like bonding material 20 is pressed and spread, the particles in the bonding material 20 collide with each other in the central portion 21 and the stretched portions 22 of the bonding material 20, leading the bonding material 20 to attain a denser state. Whereas, in the retreated portion 23 of the extended portion 22, the bonding material 20 spreads into space and therefore attains a sparse state.

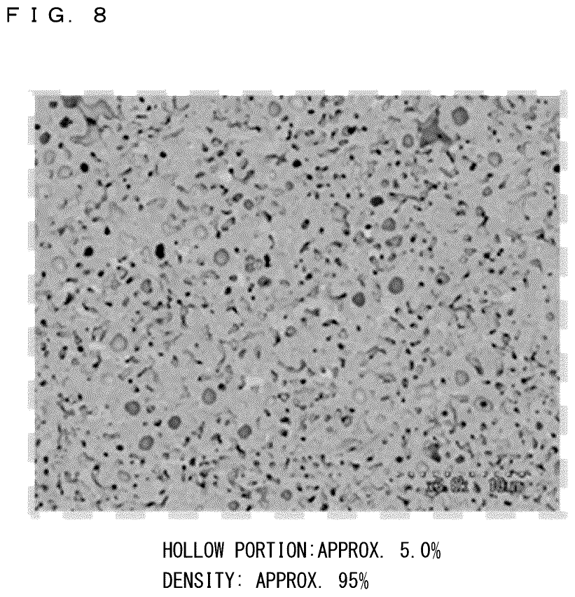

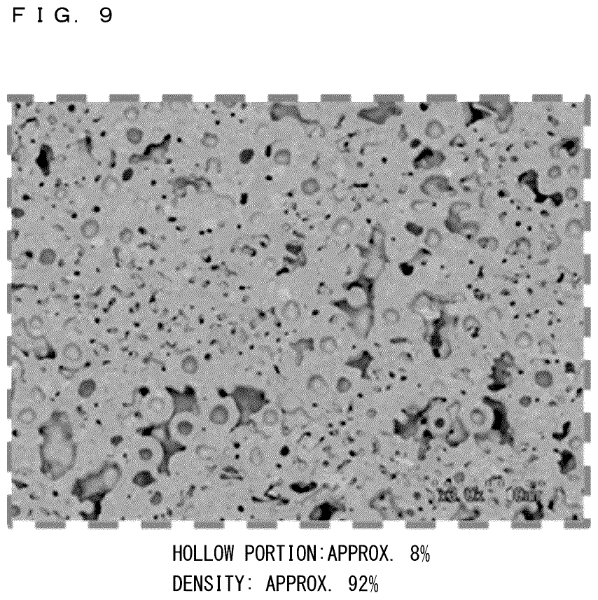

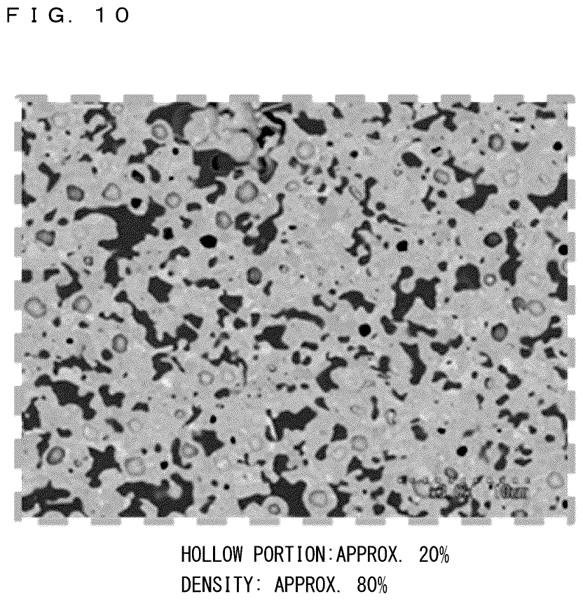

FIGS. 8 to 10 illustrate images of the states of the bonding material 20 after sintering. FIG. 8 is an image observed of a portion formed by the central portion 21 of the bonding material 20 being pressed and spread (near the central portion of the object to be bonded 30), FIG. 9 is an image observed of a portion formed by the extended portion 22 of the bonding material 20 being pressed and spread (near the vertex of the object to be bonded 30), and FIG. 10 is an image observed of a portion formed by the retreated portion 23 of the bonding material 20 being pressed and spread (near the side of the object to be bonded 30). The void ratios (proportion of the hollow portion) were 10% or less (that is, the density was 90% or more) in the portion formed by the central part 21 being pressed and spread (FIG. 8) and the portion formed by the extended portion 22 being pressed and spread (FIG. 9), whereas, the void ratio was about 20% (that is, the density was about 80%) in the portion formed by the retreated portion 23 being pressed and spread.

By achieving such a distribution of the void ratios in the bonding material 20, cracks in the bonding material 20, particularly at the corners, are suppressed. Further, when a semiconductor chip is adopted as the object to be bonded 30, the high density of the bonding material 20 near the central portion of the object to be bonded 30 can contribute to improving the heat dissipation of the semiconductor chip. In this manner, in Embodiment, the density of the bonding material 20 can be controlled.

As described above, according to the method of manufacturing a semiconductor device according to Embodiment, in the step of bonding the object to be bonded 30 onto the base material 10 using the paste-like bonding material 20, the spread of the bonding material 20 to the corners of the object to be bonded 30 and control of a density of a bonding material 20 are both established.

It should be noted that Embodiments can be arbitrarily combined and can be appropriately modified or omitted.

### APPENDIX

Hereinafter, the aspects of the present disclosure will be collectively described as Appendices.

### Appendix 1

A method of manufacturing a semiconductor device, comprising the steps of:
(a) supplying a paste-like bonding material on a base material; and
(b) placing an object to be bonded on the bonding material, pressing down the bonding material with the object to be bonded, and bonding the object to be bonded onto the base material by the bonding material, wherein
the object to be bonded has a rectangular shape in plan view,
in the step (a), when the object to be bonded is placed on the bonding material, the bonding material supplied onto the base material includes a central portion located at a center of the object to be bonded, an extended portion extending from the central portion toward each vertex of the object to be bonded and having a shape corresponding to a corner shape of each vertex of the object to be bonded, and a retreated portion that is retreated from each side of the object to be bonded, and,
after the step (b), a distance of 40 μm or more is secured from an upper surface of the object to be bonded to an upper end of the bonding material that has crept up along a side surface of the object to be bonded.

### Appendix 2

The method of manufacturing the semiconductor device according to Appendix 1, wherein
the bonding material is a non-melting bonding material.

### Appendix 3

The method of manufacturing the semiconductor device according to Appendix 1 or 2, wherein
in the step (b), a portion of the bonding material formed by the retreated portion being pressed and spread reaches each side of the rectangular shape of the object to be bonded.

### Appendix 4

The method of manufacturing the semiconductor device according to any one of Appendices 1 to 3, wherein
in the bonding material after the step (b), a void ratio is higher in a portion formed by the retreated portion being pressed and spread than a void ratio of the central portion.

### Appendix 5

A semiconductor device comprising
an object to be bonded having a rectangular shape bonded onto a base material via a bonding material, wherein
the bonding material is in contact with each vertex and each side of the object to be bonded, and a distance of 40 μm or more is secured from an upper surface of the object to be bonded to an upper end of the bonding material that has crept up along a side surface of the object to be bonded.

### Appendix 6

The semiconductor device according to Appendix 5, wherein
the bonding material is a non-melting bonding material.

### Appendix 7

The semiconductor device according to Appendix 5 or 6, wherein
in the bonding material, a void ratio is higher near each side of the object to be bonded than a void ratio near each vertex of the object to be bonded.

While the invention has been illustrated and described in detail, the foregoing description is in all aspects illustrative and not restrictive. It is therefore understood that numerous modifications and variations can be devised without departing from the scope of the invention.

What is claimed is:

1. A method of manufacturing a semiconductor device, comprising the steps of:
(a) supplying a paste-like bonding material on a base material; and
(b) placing an object to be bonded on the bonding material, pressing down the bonding material with the object to be bonded, and bonding the object to be bonded onto the base material by the bonding material, wherein
the object to be bonded has a rectangular shape in plan view,
in the step (a), when the object to be bonded is placed on the bonding material, the bonding material supplied onto the base material includes a central portion located at a center of the object to be bonded, an extended portion extending from the central portion toward each vertex of the object to be bonded and having a shape corresponding to a corner shape of each vertex of the object to be bonded, and a retreated portion that is retreated from each side of the object to be bonded, and,
after the step (b), a distance of 40 μm or more is secured from an upper surface of the object to be bonded to an upper end of the bonding material that has crept up along a side surface of the object to be bonded.

2. The method of manufacturing the semiconductor device according to claim 1, wherein
the bonding material is a non-melting bonding material.

3. The method of manufacturing the semiconductor device according to claim 1, wherein
in the step (b), a portion of the bonding material formed by the retreated portion being pressed and spread reaches each side of the rectangular shape of the object to be bonded.

4. The method of manufacturing the semiconductor device according to claim 2, wherein
in the step (b), a portion of the bonding material formed by the retreated portion being pressed and spread reaches each side of the rectangular shape of the object to be bonded.

5. The method of manufacturing the semiconductor device according to claim 1, wherein
in the bonding material after the step (b), a void ratio is higher in a portion formed by the retreated portion being pressed and spread than a void ratio of the central portion.

6. The method of manufacturing the semiconductor device according to claim 2, wherein
in the bonding material after the step (b), a void ratio is higher in a portion formed by the retreated portion being pressed and spread than a void ratio of the central portion.

7. The method of manufacturing the semiconductor device according to claim 3, wherein
in the bonding material after the step (b), a void ratio is higher in a portion formed by the retreated portion being pressed and spread than a void ratio of the central portion.

8. The method of manufacturing the semiconductor device according to claim 4, wherein
in the bonding material after the step (b), a void ratio is higher in a portion formed by the retreated portion being pressed and spread than a void ratio of the central portion.

9. A semiconductor device comprising
an object to be bonded having a rectangular shape bonded onto a base material via a bonding material, wherein
the bonding material is in contact with each vertex and each side of the object to be bonded, and a distance of 40 μm or more is secured from an upper surface of the object to be bonded to an upper end of the bonding material that has crept up along a side surface of the object to be bonded.

10. The semiconductor device according to claim 9, wherein
the bonding material is a non-melting bonding material.

11. The semiconductor device according to claim 9, wherein
in the bonding material, a void ratio is higher near each side of the object to be bonded than a void ratio near each vertex of the object to be bonded.

12. The semiconductor device according to claim 10, wherein
in the bonding material, a void ratio is higher near each side of the object to be bonded than a void ratio near each vertex of the object to be bonded.
